(19) United States
(12) Patent Application Publication
(10) Pub. No.: US 2015/0160273 A1
(43) Pub. Date: Jun. 11, 2015

(54) METHOD AND PLANT FOR SIMULTANEOUS MONITORING OF EVENTS OF AN INDUSTRIAL PRODUCTION PLANT WHICH ARE ASSOCIATED WITH LOCATION AND INFLUENCE ENERGY CONSUMPTION

(71) Applicant: INPRO INNOVATIONSGESELLSCHAFT FUR FORTGESCHRITTENE PRODUKTIONSSYSTEME IN DER FAHRZEUGINDUSTRIE MBH, Berlin (DE)

(72) Inventor: Sabine Thieme, Berlin (DE)

(73) Assignee: INPRO INNOVATIONSGESELLSCHAFT FOR FORTGESCHRITTENE PRODUKTIONSSYSTEME IN DER FAHRZEUGINDUSTRIE MBH, Berlin (DE)

(21) Appl. No.: 14/403,970

(22) PCT Filed: Sep. 17, 2013
(86) PCT No.: PCT/DE2013/000539

§ 371 Date: Nov. 25, 2014

(30) Foreign Application Priority Data
Sep. 18, 2012 (DE) 10 2012 018 522.7

(51) Int. Cl. G01R 21/00

(52) U.S. Cl. CPC G01R 21/006

(57) ABSTRACT

Simultaneous monitoring of events of an industrial production plant associated with a location and influencing energy consumption, includes detecting current consumption of energy and assigning time-related and location-related measured values to it. An algorithm is specified for determination of identification numbers (k), which are related to differently-located production areas (l) and/or to individual works (j), of the transmitted measured values of the current energy consumptions and/or of the current consumption. Limiting values are displayed in an electronic comparator and a degree of deviation between current energy consumption and/or current consumptions of media are evaluated.

### TECHNICAL FIELD OF THE INVENTION

The invention relates to a method for parallel (congruent) tracking of location-assigned energy-consumption-influencing events of an industrial production plant, such as a motor vehicle production plant with an energy supply network.

The invention furthermore relates to a plant for parallel (congruent) tracking of location-assigned energy-consumption-influencing events of an industrial production plant, such as a motor vehicle production plant.

### BACKGROUND OF THE INVENTION

In complex production systems, such as e.g. in the automotive industry, a high quality of the products with a short throughput time is striven for, which entails an increase of energy costs. An attempt is made to improve the energy efficiency both by optimising the production and by minimising energetic losses in manufacturing processes of an industrial production plant.

FIG. 1 of the drawings shows a known image, which has been disclosed during a talk at the DPO conference in May 2006 and from which an overview of percentage energy consumptions in relation to total energy consumption in automotive production emerges.

A method is known (DE10 2009 022 434 B3) for automatically identifying, monitoring and minimising location-assigned energetic losses of an industrial production plant, such as a motor vehicle production plant, in which method, the energetic losses arising at least in each differently located individual assembly section of the differently located manufacturing areas of the production plant, which energetic losses are principally manifested as thermal losses, are detected by signal using at least one thermal imaging camera system. The measuring signal containing the energetic losses of the respective individual assembly section is simultaneously transmitted with a location/position signal of at least one location/position signal generator, which is assigned to the corresponding individual assembly section in each case, to an analysis station. In the analysis station, the measuring signals and assigned position signals of all differently located individual assembly sections are digitally processed and stored in a database in a time- and location-based manner. Signal commands, the content of which is based on the corresponding database-recorded energetic losses in each case, are then transmitted from the analysis station via feedback to respective control systems of the individual assembly sections to minimise or switch off the energetic losses arising in each case.

### SUMMARY OF THE INVENTION

The present invention is based on the object of configuring a method and a plant of the type mentioned at the beginning in such a manner that for an efficient energy management of the industrial production plant, such as a motor vehicle plant, a continuous comprehensive electronic and/or visual location- and/or time-based provision of information, which includes a location- and/or time-based illustration and evaluation of exceptional events of the production process, is available at every differently located individual assembly section and/or every differently located manufacturing area of the industrial production plant.

This object is achieved according to the embodiments of the invention by a method of the type mentioned at the beginning comprising electrical energy and media l=1, 2, . . . , p, which are used as energy carriers, having a multiplicity of differently located manufacturing areas i=1, 2, . . . , n and having a number of differently located individual assembly sections j=1, 2, . . . , m in each case, to which in each case an energy requirement, which is predetermined in terms of time periods (as a percentage), and/or a requirement, which is predetermined in terms of time periods (as a percentage), of the media l=1, 2, . . . , p, which are used as energy carriers, for supply power of the energy supply network, is to be assigned, and at which a continuous measurement of the current (percentage) consumption of the total power of the energy supply network takes place in each case and comprising the successive method steps:
the current consumptions of energy and the media l=1, 2, . . . , p used as energy carriers or only the current consumptions of the media l=1, 2, . . . , p used as energy carriers are recorded for each differently located manufacturing area i=1, 2, . . . , n and/or each differently located individual assembly section j=1, 2, . . . , m of the differently located manufacturing areas i=1, 2, . . . , n of the production plant, and
the predetermined energy consumptions (to be achieved) and the predetermined consumptions (to be achieved) of the media l=1, 2, . . . , p used as energy carriers or only the predetermined consumptions (to be achieved) of the media l=1, 2, . . . , p used as energy carriers are determined for a predetermined time period for each differently located manufacturing area i=1, 2, . . . , n and/or each differently located individual assembly section j=1, 2, . . . , m of the differently located manufacturing areas i=1, 2, . . . , n of the production plant, and assigned to time- and location-based measured values,
the recorded measured values of the current energy consumptions and the current consumptions of the media l=1, 2, . . . , p used as energy carriers or only the current consumptions of the media l=1, 2, . . . , p used as energy carriers and the assigned time- and location-based measured values of the predetermined energy consumption for the predetermined time period and/or the predetermined requirement of the media l=1, 2 . . . . , p used as energy carriers of the respective differently located manufacturing areas i=1, 2, . . . , n and/or the respective differently located individual assembly sections j=1, 2, . . . , m of the differently located manufacturing areas i=1, 2, . . . , n of the production plant are electronically supplied to a database of an analysis station (control centre) via a server infrastructure,
in the analysis station (control centre) an algorithm for determining parameters k=1, 2, . . . , o—based on the differently located manufacturing areas i=1, 2, . . . , n and/or on the individual assembly sections j=1, 2, . . . , m of the differently located manufacturing areas i=1, 2, . . . , n—of the transmitted measured values of the current energy consumptions and the current consumptions of the media l=1, 2, . . . , p used as energy carriers or only the current consumptions of the media l=1, 2, . . . , p used as energy carriers and the predetermined energy requirement for the predetermined time period and the predetermined requirement of the media l=1, 2, . . . , p used as energy carriers or only the predetermined requirement of the media l=1, 2, . . . , p used as energy carriers is determined and the parameters k=1, 2, . . . , o are visualised,
in the analysis station (control centre), the current energy consumptions and the current consumptions of the media l=1, 2, . . . , p used as energy carriers or only the current consumptions of the media l=1, 2, . . . , p used as energy carriers and/or the previously determined parameters k=1, 2, . . . , o of the predetermined energy requirement and the predetermined requirement of the media l=1, 2, . . . , p used as energy carriers or only the predetermined requirement of the media l=1, 2, . . . , p used as energy carriers for the predetermined time period are compared with predetermined critical limit values in an electronic comparator of the analysis station (control centre) and visualised for the differently located manufacturing areas i=1, 2, . . . , n and/or for the individual assembly sections j=1, 2, . . . , m of the differently located manufacturing areas i=1, 2, . . . , n,
in the electronic comparator of the analysis station (control centre), for the differently located manufacturing areas i=1, 2, . . . , n and/or for the individual assembly sections j=1, 2, . . . , m of the differently located manufacturing areas i=1, 2, . . . , n, the degree of deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period is determined and evaluated and also over- and/or undershooting that occurs is visualised on the basis of predetermined critical limit values,
for the differently located manufacturing areas i=1, 2, . . . , n and/or for the individual assembly sections j=1, 2, . . . , m of the differently located manufacturing areas i=1, 2, . . . , n, a deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period is investigated for an exceptional event in the production process and the latter event is visualised if appropriate, and
for the differently located manufacturing areas i=1, 2, . . . , n and/or for the individual assembly sections j=1, 2, . . . , m of the differently located manufacturing areas i=1, 2, . . . , n, for the case of a deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period without a detected exceptional event in the production process, the deviation is visualised, the cause of the deviation is determined and measures are introduced for optimisation.

Natural gas, coal, coke, oil, water, nitrogen, compressed air and heat for heating can be used as media l=1, 2, . . . , p used as energy carriers.

The differently located manufacturing areas i=1, 2, . . . , n can be body shell work, assembly, pressing plant, painting, logistics, tool making, stock-keeping and the differently located individual assembly sections j=1, 2, . . . , m can be the manufacturing of castings, coil cutting in the pressing plant, side wall manufacture, floor assembly manufacture, roof manufacture, dip coating, paint application, cockpit assembly, gearbox manufacture, electric cabling and wheel assembly.

According to an embodiment, the parameters k=1, 2, . . . , o are the energy requirement per unit production, the energy requirement per unit time and also average, minimum and/or maximum values of the measured values of the current energy consumptions and/or the consumptions of the media l=1, 2, . . . , p used as energy carriers transmitted to the analysis station (control centre) and the predetermined energy requirement for the predetermined time period and/or the predetermined requirement of the media l=1, 2, . . . , p used as energy carriers.

According to another embodiment, the over- and/or undershooting of the predetermined critical limit values when comparing between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period are classified for the differently located manufacturing areas i=1, 2, . . . , n and/or for the individual assembly sections j=1, 2, . . . , m of the differently located manufacturing areas i=1, 2, . . . , n by the comparator as defective and acoustically and/or visually indicated by an electronic signal generator connected to the comparator on the output side.

The predetermined time periods can lie in the past, in the present or in the future. For the predetermined future time periods, the energy requirement to be expected and/or the requirement to be expected of the media l=1, 2, . . . , p used as energy carriers for the differently located manufacturing areas i=1, 2, . . . , n and/or for the individual assembly sections j=1, 2, . . . , m of the differently located manufacturing areas i=1, 2, . . . , n are preferably also extrapolated or prognosticated.

In an embodiment, the visualisation of the current energy consumptions and/or the current consumptions of the media l=1, 2, . . . , p used as energy carriers and the energy requirement predetermined for the predetermined time period and/or the predetermined requirement of the media l=1, 2, . . . , p used as energy carriers for the differently located manufacturing areas i=1, 2, . . . , n and/or for the differently located individual assembly sections j=1, 2, . . . , m of the differently located manufacturing areas i=1, 2, . . . , n takes place by means of a tachometer and/or on a timeline in a thermometer representation, in which predetermined critical limit values and/or transition areas are marked with a colour.

The exceptional events in the production process can be extra shifts, works meetings, maintenance measures, optimisation measures, production programme changes, expansion changes, assembly and/or disassembly measures or the like.

The visualisation can take place on electronic terminals connected to the server infrastructure via the internal network and/or the Internet and/or using mobile electronic terminals, which are located within and/or outside the production plant, the server infrastructure and the electronic terminals and/or the mobile electronic terminals being bidirectionally connected.

The object of the embodiments of the present invention is likewise achieved by means of a plant of the type mentioned at the beginning, which has the following features:

a server infrastructure, which has a central server with a database, in which a multiplicity of information is to be collated and stored, which is to be provided by a multiplicity of electronic terminals and/or mobile electronic terminals connected to the central server via an internal, local and/or global network,
wherein the current energy consumptions and/or the current consumptions of the media l=1, 2, . . . , p used as energy carriers of measuring systems of the differently located manufacturing areas i=1, 2, . . . , n and/or the individual assembly sections j=1, 2, . . . , m of the differently located manufacturing areas i=1, 2, . . . , n are to be recorded and input into the database and stored in the same,
the production plan is to be input into the database of the central server,
the measured values of the consumptions of energy and/or the consumptions of the media l=1, 2, . . . , p used as energy carriers stored in the database are to be called up or to be transmitted bidirectionally via the server infrastructure via a local, internal and/or global network and to be visualised on electronic terminals and/or mobile electronic terminals,
an algorithm is to be determined in the central server for determining the parameters k=1, 2, . . . , o, based on the differently located manufacturing areas i=1, 2, . . . , n and/or on the individual assembly sections j=1, 2, . . . , m of the differently located manufacturing areas i=1, 2, . . . , n, of the measured values, transmitted to the database, of the current energy consumptions and/or the current consumptions of the media l=1, 2, . . . , p used as energy carriers and of the predetermined energy requirement for the predetermined time period and/or the predetermined requirement of the media l=1, 2, . . . , p used as energy carriers,
for the differently located manufacturing areas i=1, 2, . . . , n and/or for the individual assembly sections j=1, 2, . . . , m of the differently located manufacturing areas i=1, 2, . . . , n, the current energy consumptions and/or the current consumptions of the media l=1, 2, . . . , p used as energy carriers and/or the previously determined parameters k=1, 2, . . . , o of the predetermined energy requirement and/or the predetermined requirement of the media l=1, 2, . . . , p used as energy carriers for the predetermined time period are to be compared with predetermined critical limit values in an electronic comparator in the central server and to be visualised, and
in the electronic comparator of the central server, for the differently located manufacturing areas i=1, 2, . . . , n and/or for the individual assembly sections j=1, 2, . . . , m of the differently located manufacturing areas i=1, 2, . . . , n, the degree of deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period is to be determined and evaluated and also over- and/or undershooting that occurs is to be visualised on the basis of predetermined critical limit values.

According to an embodiment, an electronic signal generator is connected to the electronic comparator of the central server on the output side, by means of which over- and/or undershooting of predetermined critical limit values, which have been classified by the comparator as defective, are to be indicated acoustically and/or visually. The visualisation can take place on electronic terminals and/or mobile electronic terminals as a tachometer or thermometer representation. Also, traffic lights and/or a flashing light can be provided for visual indication and/or an alarm sound and/or an alarm siren can be provided for acoustic indication.

The invention proves to be capable of taking on and displaying exceptional production events in the production process, such as e.g. extra shifts, works meetings, maintenance measures, optimisation measures, production programme changes, expansion measures, assembly and/or disassembly measures from source systems.

By collating a multiplicity of information about the production process, it is possible to better evaluate consumptions and/or the requirement for energy and/or the requirement of the media used as energy carriers and the corresponding parameters thereof, as a result of which unnecessary and complex research activities are avoided. Furthermore, the advantage results from the illustration of the consumptions and/or the requirement for energy and/or the requirement of the media used as energy carriers and/or the corresponding parameters that the differently located manufacturing areas and/or differently located individual assembly sections involved all receive the same view of energy efficiency and the effects of corresponding optimisation measures, as a result of which an isolated view is avoided.

### BRIEF DESCRIPTION OF THE DRAWINGS

The invention is now explained with reference to the drawings. In the drawings

FIG. 2 shows a block diagram, from which the method according to the invention emerges,

FIG. 3 shows a schematic illustration, from which the server infrastructure of the plant according to the invention emerges,

FIG. 4a shows a graph, in which the energy consumptions in kWh are shown over a timeline,

FIGS. 4b and 4c show schematic visualisations of the minimum and maximum values of the energy consumptions in kWh according to FIG. 3a in tachometer representation and

FIG. 5 shows a further graph, in which the energy consumptions in kWh are plotted over a timeline, a standard cleaning and a stoppage are contained in the graph.

### DETAILED DESCRIPTION OF EMBODIMENTS OF THE INVENTION

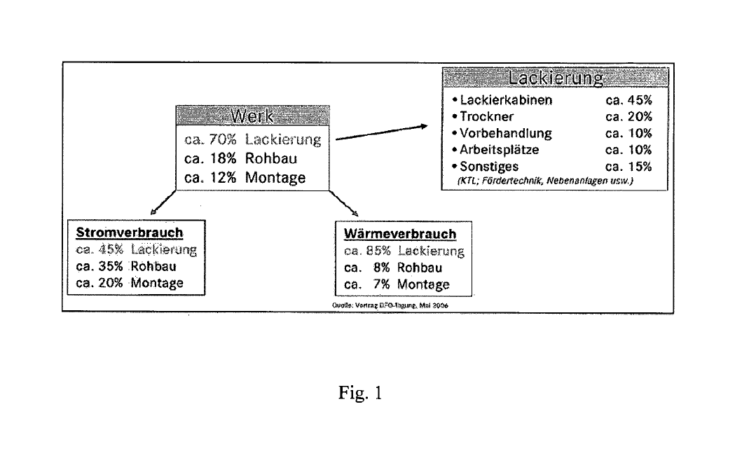

The method according to the invention emerges from FIG. 2. In manufacturing in a production plant 1, energy and/or media l=1, 2, . . . , p used as energy carriers are consumed in a number i=1, 2, . . . , n of differently located manufacturing areas with a number j=1, 2, . . . , m of differently located individual assembly sections. For example, according to FIG. 2, in the manufacturing area i=1 with the individual assembly sections j=1 and j=2, energy and/or media l=1 and l=2 used as energy carriers are consumed in the individual assembly section j=1, whilst energy and/or media l=1 and l=3 used as energy carriers are consumed in the individual assembly section j=2. By contrast, in the manufacturing area i=1 with the individual assembly section j=3, only energy or a medium l=1 used as energy carrier is consumed.

The current consumptions of energy and/or the consumptions of media l=1, 2, . . . , p used as energy carriers are recorded in each differently located manufacturing area i=1, 2, . . . , n and/or each differently located individual assembly section j=1, 2, . . . , m using a measuring system 2. Subsequently, the measured current consumptions of energy and/or the consumptions of the media l=1, 2, . . . , p used as energy carriers are transmitted to an analysis station (control centre) 3 and stored in a database 4 there. The measured values of the consumptions of energy and/or the consumptions of the media l=1, 2, . . . , p used as energy carriers, which are stored in the database 4, can be called up or transmitted bidirectionally via a server infrastructure 5 via a local, internal and/or global network 6 and visualised on electronic terminals 7 and/or mobile electronic terminals 8. The visualisations of the consumptions of energy and/or the consumptions of the media l=1, 2, . . . , p used as energy carriers in this case preferably takes place tabularly or in a graphical representation over a timeline.

Various parameters k=1, 2, . . . , o for a predetermined time period are determined in accordance with an algorithm for the measured values of the consumptions of energy and/or the consumptions of the media l=1, 2, . . . , p used as energy carriers, which are stored in the database 4, the parameters preferably representing average, minimum and/or maximum values of the consumptions of energy and/or the consumptions of the media l=1, 2, . . . , p used as energy carriers for the predetermined time period and also the consumptions of energy or the consumptions of the media l=1, 2, . . . , p used as energy carriers per unit production and/or unit time.

The parameters k=1, 2, . . . , o are subsequently compared with predetermined critical limit values in a comparator 9, evaluated and visualised. In this case, the visualisation preferably takes place via a server infrastructure 5 on electronic terminals 7 and/or mobile electronic terminals 8 in tachometer or thermometer representation, uncritical areas being illustrated green, transition areas being illustrated yellow and critical areas being illustrated red. Preferably, the visualisation takes place in each manufacturing area i=1, 2, . . . , m and/or each individual assembly unit j=1, 2, . . . , m individually. In addition to a visualisation in the analysis station (control centre) 3, the visualisation can however also take place outside of the production plant 1, i.e. on electronic terminals 7 and/or mobile electronic terminals 8, which are connected to the server infrastructure 5 via a global network connection 6.

Over- and/or overshooting of predetermined critical limit value, which have been classified by the comparator 9 as defective, can be indicated acoustically and/or visually by means of an electronic signal generator connected to the comparator 9 on the output side. In addition to a tachometer or thermometer representation on electronic terminals 7 and/or mobile electronic terminals 8, traffic lights or a flashing light can preferably be used for visual display and an alarm sound or an alarm siren can be used for acoustic indication. An electronic data transmission in the form of a text message to electronic terminals 7 and/or mobile electronic terminals 8 likewise come into consideration.

When comparing the production plan 10 stored in the database 4 with the parameters k=1, 2, . . . , o, a deviation between current energy consumptions and/or current consumptions the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period can be investigated for an exceptional event in the production process and an exceptional event in the production process, such as e.g. extra shifts, works meetings, maintenance measures, optimisation measures, production programme changes, expansion measures, assembly and/or disassembly measures or the like and visualised if appropriate.

If no exceptional event in the production process has been detected for the predetermined time period, the cause of the deviation is determined and corresponding measures are introduced for troubleshooting.

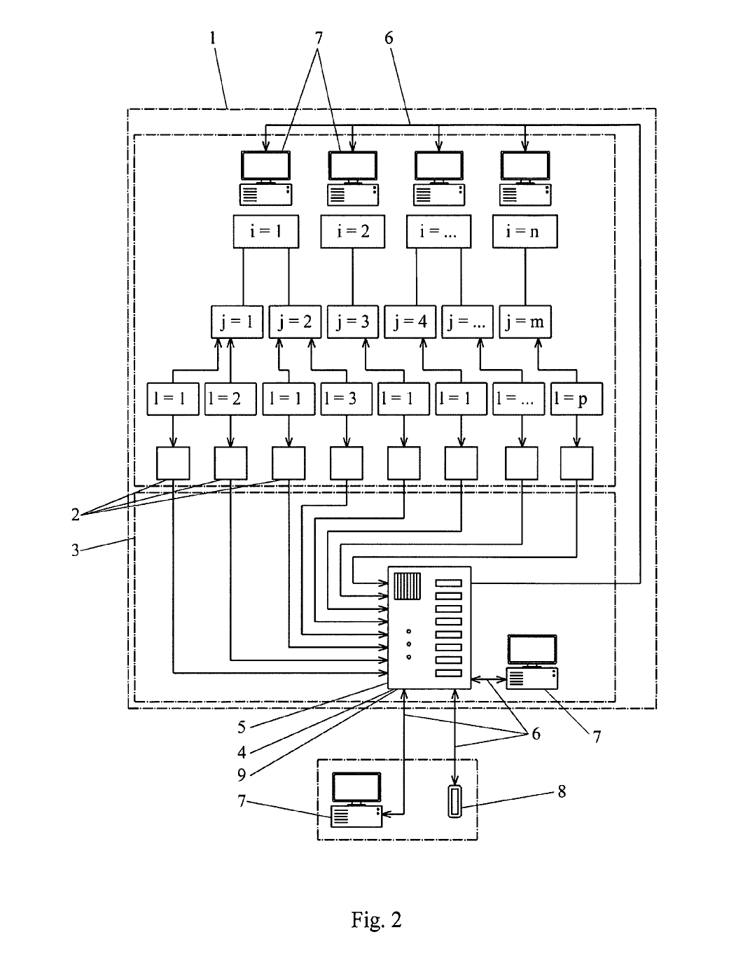

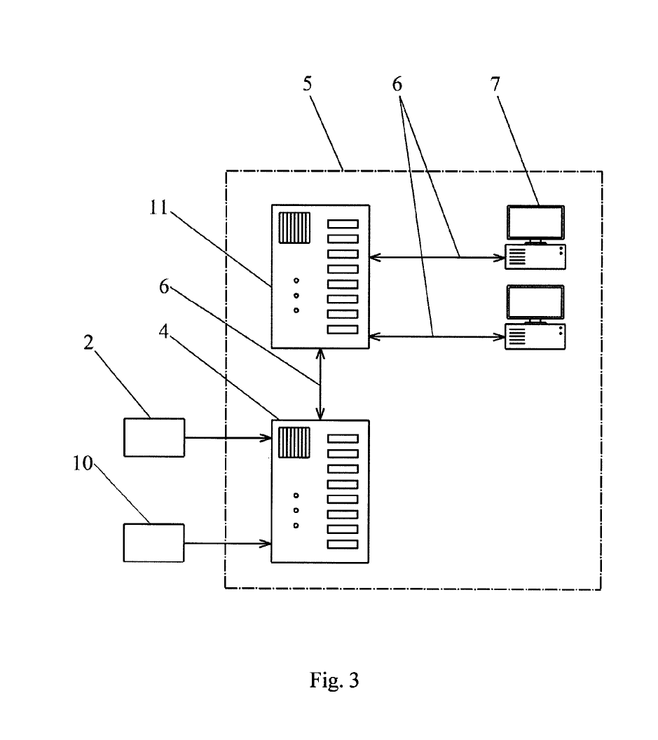

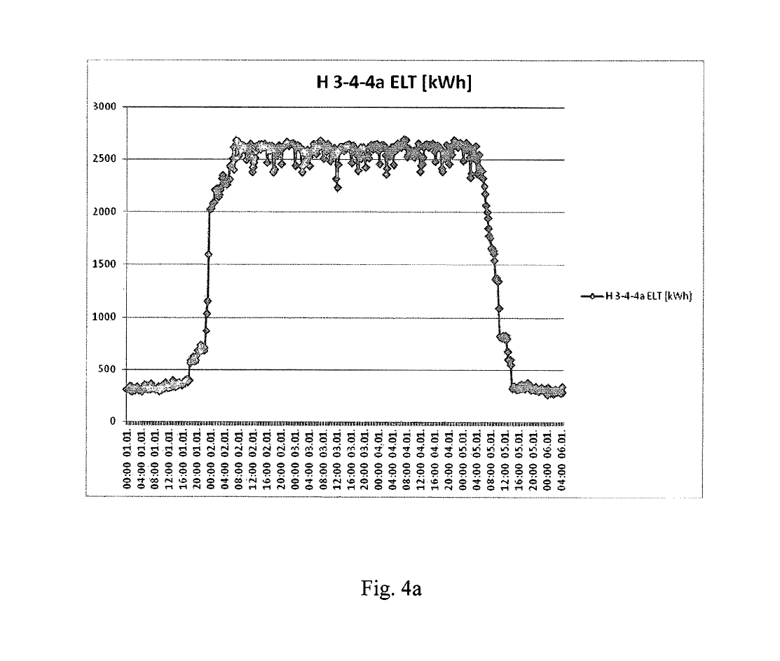

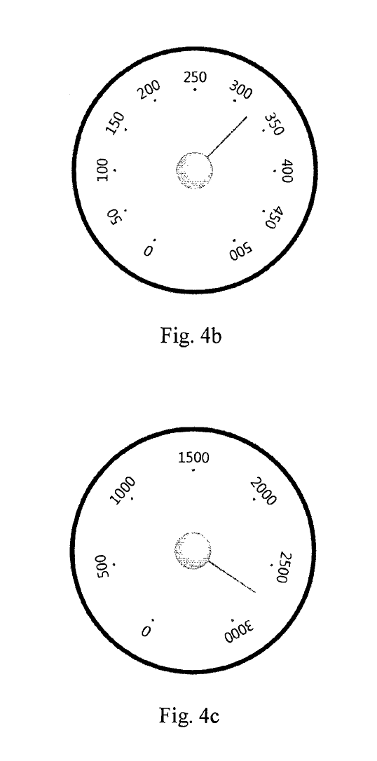

The server infrastructure 5 is illustrated schematically in FIG. 3. Measured values of the current consumptions of energy and/or the current consumptions of the media l=1, 2, . . . , p used as energy carriers are transmitted by a measuring system 2 to the database 4 and stored after recording. The production plan 10 is likewise transmitted to the database 4 and stored. The parameters k=1, 2, . . . , o are determined in accordance with an algorithm on a central server 11. Subsequently, the parameters k=1, 2, . . . , o are compared with predetermined limit values and evaluated by the electronic comparator 9 on the central server 11. Here, the critical limit values can be predetermined for the central server 11 in advance by electronic terminals 7 and/or mobile electronic terminals 8. The visualisation preferably takes place via the central server 11 on electronic terminals 7 and/or mobile electronic terminals 8 in tachometer or thermometer representation or as a graphical diagram of the consumptions over a timeline. FIG. 4a shows a graph of this type of the energy consumption in kWh over a timeline. FIGS. 4b and 4c in each case show a tachometer representation for the minimum value or maximum value parameters according to FIG. 4a.

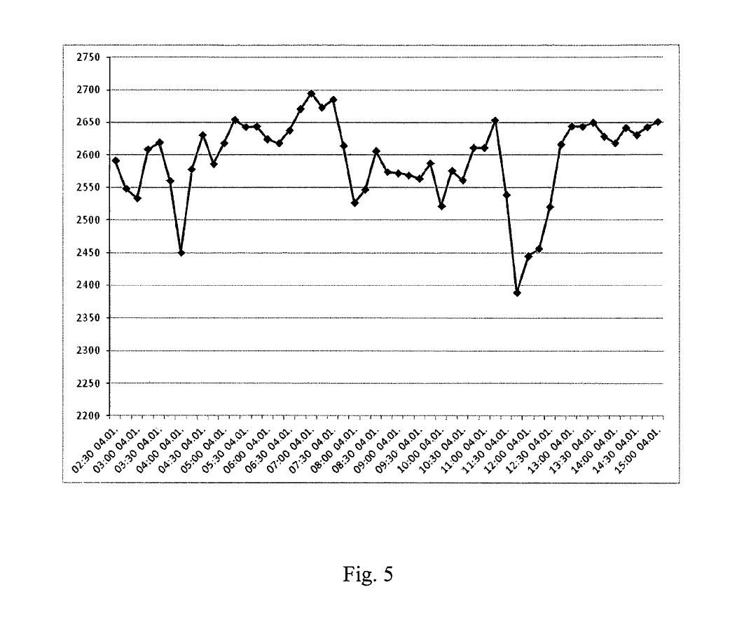

FIG. 5 shows a further graph of the energy consumption in kWh over a timeline for a manufacturing area and/or an individual assembly section of a production plant 1, from which, for a time period, a drop in energy consumption during standard cleaning and a stoppage can be drawn in each case.

### REFERENCE LIST

1 Production plant
2 Measuring systems
3 Analysis station (control centre)
4 Database
5 Server infrastructure
6 Local, internal and/or global network
7 Electronic terminals
8 Mobile electronic terminals
9 Electronic comparator
10 Production plan
11 Central server
i Manufacturing areas
j Individual assembly sections
k Parameters
l Media used as energy carriers

1. A method for parallel tracking of location-assigned energy-consumption-influencing events of an industrial production plant, such as a motor vehicle production plant with an energy supply network, comprising electrical energy and media l=1, 2, . . . , p, which are used as energy carriers, having a multiplicity of differently located manufacturing areas i=1, 2, . . . , n and having a number of differently located individual assembly sections j=1, 2, . . . , m in each case, to which in each case an energy requirement, which is predetermined in terms of time periods (as a percentage), and/or a requirement, which is predetermined in terms of time periods (as a percentage), of the media l=1, 2, . . . , p, which are used as energy carriers, for supply power of the energy supply network, is to be assigned, and at which a continuous measurement of the current (percentage) consumption of the total power of the energy supply network takes place in each case, wherein the method has the following method steps:
the current consumptions of energy and/or the media l=1, 2, . . . , p used as energy carriers are recorded for each differently located manufacturing area i=1, 2, . . . , n and/or each differently located individual assembly section j=1, 2, . . . , m of the differently located manufacturing areas i=1, 2, . . . , n of the production plant, and
the predetermined energy consumptions (to be achieved) and the predetermined consumptions (to be achieved) of the media l=1, 2, . . . , p used as energy carriers or only the predetermined consumptions (to be achieved) of the media l=1, 2, . . . , p used as energy carriers are determined for a predetermined time period for each differently located manufacturing area i=1, 2, . . . , n and/or each differently located individual assembly section j=1, 2, . . . , m of the differently located manufacturing areas i=1, 2, . . . , n of the production plant, and assigned to time- and location-based measured values,
the recorded measured values of the current energy consumptions and the current consumptions of the media l=1, 2, . . . , p used as energy carriers or only the current consumptions of the media l=1, 2, . . . , p used as energy carriers and the assigned time- and location-based measured values of the predetermined energy consumption for the predetermined time period and/or the predetermined requirement of the media l=1, 2 . . . , p used as energy carriers of the respective differently located manufacturing areas i=1, 2, . . . , n and/or the respective differently located individual assembly sections j=1, 2, . . . , m of the differently located manufacturing areas i=1, 2, . . . , n of the production plant are electronically supplied to a database of an analysis station (control centre) via a server infrastructure,
in the analysis station (control centre) an algorithm for determining parameters k=1, 2, . . . , o—based on the differently located manufacturing areas i=1, 2, . . . , n and/or on the individual assembly sections j=1, 2, . . . , m of the differently located manufacturing areas i=1, 2, . . . , n—of the transmitted measured values of the current energy consumptions and the current consumptions of the media l=1, 2, . . . , p used as energy carriers or only the current consumptions of the media l=1, 2, . . . , p used as energy carriers and the predetermined energy requirement for the predetermined time period and the predetermined requirement of the media l=1, 2, . . . , p used as energy carriers or only the predetermined requirement of the media l=1, 2, . . . , p used as energy carriers is determined and the parameters k=1, 2, . . . , o are visualised,
in the analysis station (control centre), the current energy consumptions and the current consumptions of the media l=1, 2, . . . , p used as energy carriers or only the current consumptions of the media l=1, 2, . . . , p used as energy carriers and/or the previously determined parameters k=1, 2, . . . , o of the predetermined energy requirement and the predetermined requirement of the media l=1, 2, . . . , p used as energy carriers or only the predetermined requirement of the media l=1, 2, . . . , p used as energy carriers for the predetermined time period are compared with predetermined critical limit values in an electronic comparator of the analysis station (control centre) and visualised for the differently located manufacturing areas i=1, 2, . . . , n and/or for the individual assembly sections j=1, 2, . . . , m of the differently located manufacturing areas i=1, 2, . . . , n,
in the electronic comparator of the analysis station (control centre), for the differently located manufacturing areas i=1, 2, . . . , n and/or for the individual assembly sections j=1, 2, . . . , m of the differently located manufacturing areas i=1, 2, . . . , n, the degree of deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period is determined and evaluated and also over- and/or undershooting that occurs is visualised on the basis of predetermined critical limit values,
for the differently located manufacturing areas i=1, 2, . . . , n and/or for the individual assembly sections j=1, 2, . . . , m of the differently located manufacturing areas i=1, 2, . . . , n, a deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period is investigated for an exceptional event in the production process and the latter event is visualised if appropriate, and
for the differently located manufacturing areas i=1, 2, . . . , n and/or for the individual assembly sections j=1, 2, . . . , m of the differently located manufacturing areas i=1, 2, . . . , n, for the case of a deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period without a detected exceptional event in the production process, the deviation is visualised, the cause of the deviation is determined and measures are introduced for optimisation.

2. The method according to claim 1, characterised in that the predetermined time periods can lie in the past, in the present or in the future.

3. The method according to claim 1,
characterised in that natural gas, coal, coke, oil, water, nitrogen, compressed air and heat for heating are used as media l=1, 2, . . . , p used as energy carriers.

4. The method according to claim 1, characterised in that the differently located manufacturing areas i=1, 2, . . . , n are body shell work, assembly, pressing plant, painting, logistics, tool making, stock-keeping and the like.

5. The method according to claim 1, characterised in that the differently located individual assembly sections j=1, 2, . . . , m are the manufacturing of castings, coil cutting in the pressing plant, side wall manufacture, floor assembly manufacture, roof manufacture, dip coating, paint application, cockpit assembly, gearbox manufacture, electric cabling and wheel assembly.

6. The method according to claim 1, characterised in that the parameters k=1, 2, . . . , o are the energy requirement per unit production, the energy requirement per unit time and also average, minimum and/or maximum values of the measured values of the current energy consumptions and/or the current consumptions of the media l=1, 2, . . . , p used as energy carriers transmitted to the analysis station (control centre) and the energy requirement for the predetermined time period and/or the predetermined requirement of the media l=1, 2, . . . , p used as energy carriers.

7. The method according to claim 1, characterised in that over- and/or undershooting of the predetermined critical limit values when comparing between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p used as energy carriers for the predetermined time period are classified for the differently located manufacturing areas i=1, 2, . . . , n and/or for the individual assembly sections j=1, 2, . . . , m of the differently located manufacturing areas i=1, 2, . . . , n by the comparator as defective and acoustically and/or visually indicated by an electronic signal generator connected to the comparator on the output side.

8. The method according to claim 1, characterised in that the visualisation of the current energy consumptions and/or the consumptions of the media l=1, 2, . . . , p used as energy carriers and the energy requirement to be predetermined for the predetermined time period and/or the predetermined requirement of the media l=1, 2, . . . , p used as energy carriers for the differently located manufacturing areas i=1, 2, . . . , n and/or for the differently located individual assembly sections j=1, 2, . . . , m of the differently located manufacturing areas i=1, 2, . . . , n takes place by means of a traffic light, tachometer and/or thermometer representation, in which predetermined critical limit values and/or transition areas are marked with a colour.

9. The method according to claim 1, characterised in that the exceptional events in the production process are extra shifts, works meetings, maintenance measures, optimisation measures, production programme changes, expansion changes, assembly and/or disassembly measures or the like.

10. The method according to claim 1, characterised in that the visualisation takes place on electronic terminals connected to the server infrastructure via the internal network and/or the Internet and/or using mobile electronic terminals, which are located within and/or outside the production plant, wherein the server infrastructure and the electronic terminals and/or the mobile electronic terminals are bidirectionally connected.

11. A plant for parallel tracking of location-assigned energy-consumption-influencing events of an industrial production plant, such as a motor vehicle production plant (1) with an energy supply network, comprising electrical energy and media l=1, 2, . . . , p, which are used as energy carriers, having a multiplicity of differently located manufacturing areas i=1, 2, . . . , n and having a number of differently located individual assembly sections j=1, 2, . . . , m in each case, to which in each case an energy requirement, which is predetermined in terms of time periods (as a percentage), and/or a requirement, which is predetermined in terms of time periods (as a percentage), of the media l=1, 2, . . . , p, which are used as energy carriers, for supply power of the energy supply network, is to be assigned, and at which a continuous measurement of the current (percentage) consumption of the total power of the energy supply network is to be carried out in each case, having the following features:
a server infrastructure (5), which has a central server (11) with a database (4), in which a multiplicity of information is to be collated and stored, which is to be provided by a multiplicity of electronic terminals (7) and/or mobile electronic terminals (8) connected to the central server (11) via an internal, local and/or global network (6),
wherein the current energy consumptions and the current consumptions of the media l=1, 2, . . . , p used as energy carriers or only the current consumptions of the media l=1, 2, . . . , p used as energy carriers of measuring systems (2) of the differently located manufacturing areas i=1, 2, . . . , n and/or the individual assembly sections j=1, 2, . . . , m of the differently located manufacturing areas i=1, 2, . . . , n are to be recorded and input into the database (4) and stored,
the production plan (10) is to be input into the database (4) of the central server (11),
the measured values of the consumptions of energy and/or the consumptions of the media l=1, 2, . . . , p used as energy carriers stored in the database (4) are to be called up or to be transmitted bidirectionally via the server infrastructure (5) via a local, internal and/or global network (6) and to be visualised on electronic terminals (7) and/or mobile electronic terminals (8),
an algorithm is to be determined in the central server (11) for determining the parameters k=1, 2, . . . , o, based on the differently located manufacturing areas i=1, 2, . . . , n and/or on the individual assembly sections j=1, 2, . . . , m of the differently located manufacturing areas i=1, 2, . . . , n, of the measured values, transmitted to the database (4), of the current energy consumptions and/or the current consumptions of the media l=1, 2, . . . , p used as energy carriers and of the predetermined energy requirement for the predetermined time period and/or the predetermined requirement of the media l=1, 2, . . . , p used as energy carriers,
for the differently located manufacturing areas i=1, 2, . . . , n and/or for the individual assembly sections j=1, 2, . . . , m of the differently located manufacturing areas i=1, 2, . . . , n, the current energy consumptions and/or the current consumptions of the media l=1, 2, . . . , p used as energy carriers and/or the previously determined parameters k=1, 2, . . . , o of the predetermined energy requirement and/or the predetermined requirement of the media l=1, 2, . . . , p used as energy carriers for the predetermined time period are to be compared with predetermined critical limit values in an electronic comparator (9) in the central server (11) and to be visualised, and
in the electronic comparator (9) of the central server (11), for the differently located manufacturing areas i=1, 2, . . . , n and/or for the individual assembly sections j=1, 2, . . . , m of the differently located manufacturing areas i=1, 2, . . . , n, the degree of deviation between current energy consumptions and/or current consumptions of the media l=1, 2, . . . , p used as energy carriers and the parameters k=1, 2, . . . , o of the predetermined energy requirement and/or the predetermined requirement of the media l=1, 2, . . . , p for the predetermined time period is to be determined and evaluated and also over- and/or undershooting that occurs is to be visualised on the basis of predetermined critical limit values.

12. The plant according to claim 11, characterised in that an electronic signal generator is connected to the electronic comparator (9) of the central server (11) on the output side, by means of which over- and/or undershooting of predetermined critical limit values, which have been classified by the comparator (9) as defective, are to be indicated acoustically and/or visually.

13. The plant according to claim 11, characterised in that the visualisation is given on electronic terminals (7) and/or mobile electronic terminals (8) as a tachometer or thermometer representation.

14. The plant according to claim 11, characterised in that traffic lights and/or a flashing light are provided for visual indication and/or an alarm sound and/or an alarm siren are provided for acoustic indication.
